(19) United States
(12) Patent Application Publication
(10) Pub. No.: US 2025/0280199 A1
(43) Pub. Date: Sep. 4, 2025

(54) PIEZO-ACTUATED PLATFORMS FOR IMAGE SENSOR STABILIZATION

(71) Applicant: Infineon Technologies AG, Neubiberg (DE)

(72) Inventors: Mohanraj SOUNDARA PANDIAN, Unterschleißheim (DE); Malika BELLA, Ottobrunn (DE); Matthias EBERL, Taufkirchen (DE); Ilie-Ionut CRISTEA, Bucharest (RO); Boris KIRILLOV, Gratwein-Straßengel (AT); Emanuele Bruno BODINI, München (DE)

(21) Appl. No.: 19/063,945

(22) Filed: Feb. 26, 2025

(30) Foreign Application Priority Data
Mar. 1, 2024 (DE) 102024201938.0

(51) Int. Cl. H04N 23/68; H02N 2/02; H02N 2/06; H04N 23/54

(52) U.S. Cl. CPC H04N 23/687; H02N 2/028; H02N 2/062; H04N 23/54

(57) ABSTRACT

A camera module includes a movable substrate comprising a first main surface and a second main surface arranged opposite to the first main surface; an image sensor mechanically coupled to the first main surface and configured to capture image data; a piezoelectric-actuated micro-electrical-mechanical systems (MEMS) platform mechanically coupled to the second main surface such that the movable substrate and the piezoelectric-actuated MEMS platform are configured to move in unison; at least one piezoelectric actuator coupled to the piezoelectric-actuated MEMS platform; and an actuation circuit configured to receive a motion sensor signal corresponding to a movement, generate at least one actuation signal based on the motion sensor signal, and provide the at least one actuation signal to the at least one piezoelectric actuator to produce a counter mechanical response at the piezoelectric-actuated MEMS platform in response to the movement indicated by the motion sensor signal.

### CROSS-REFERENCE TO RELATED APPLICATION

This application claims priority to Germany Patent Application No. 102024201938.0 filed on Mar. 1, 2024, the content of which is incorporated by reference herein in its entirety.

### BACKGROUND

An image sensor or imager is a sensor that detects and conveys information used to form an image. It does so by converting the variable attenuation of light waves (as they pass through or reflect off objects) into signals, such as currents, that convey the information. Image sensors may be used in electronic imaging devices of both analog and digital types, which may include digital cameras, camera modules, and camera phones. A complementary metal-oxide-semiconductor (CMOS) image sensor is a type of active-pixel sensor that may be used in small consumer products, such as cameras and mobile phones.

### SUMMARY

In some implementations, a camera module includes a movable substrate comprising a first main surface and a second main surface arranged opposite to the first main surface; an image sensor configured to capture image data, wherein the image sensor is mechanically coupled to the first main surface; a piezoelectric-actuated micro-electrical-mechanical systems (MEMS) platform mechanically coupled to the second main surface of the movable substrate such that the movable substrate and the piezoelectric-actuated MEMS platform are configured to move in unison; at least one piezoelectric actuator coupled to the piezoelectric-actuated MEMS platform, wherein the at least one piezoelectric actuator is configured to provide a counter mechanical response to the piezoelectric-actuated MEMS platform; and an actuation circuit configured to receive a motion sensor signal corresponding to a movement, generate at least one actuation signal based on the motion sensor signal, and provide the at least one actuation signal to the at least one piezoelectric actuator to produce the counter mechanical response at the piezoelectric-actuated MEMS platform in response to the movement indicated by the motion sensor signal.

In some implementations, a camera module includes a movable substrate comprising a first main surface and a second main surface arranged opposite to the first main surface; an image sensor configured to capture image data, wherein the image sensor is mechanically coupled to the first main surface; a first piezoelectric-actuated MEMS platform mechanically coupled to the second main surface of the movable substrate such that the movable substrate and the first piezoelectric-actuated MEMS platform are configured to move in unison along a first axis and a second axis that is perpendicular to the first axis; a first piezoelectric actuator coupled to the first piezoelectric-actuated MEMS platform, wherein the first piezoelectric actuator is configured to provide a first counter mechanical response to the movable substrate by shifting the first piezoelectric-actuated MEMS platform along the first axis; a second piezoelectric actuator coupled to the first piezoelectric-actuated MEMS platform, wherein the second piezoelectric actuator is configured to provide a second counter mechanical response to the movable substrate by shifting the first piezoelectric-actuated MEMS platform along the second axis; and an actuation circuit configured to receive at least one motion sensor signal indicative of a movement, generate a first actuation signal based on the at least one motion sensor signal, generate a second actuation signal based on the at least one motion sensor signal, apply the first actuation signal to the first piezoelectric actuator to produce the first counter mechanical response in response to the movement indicated by the at least one motion sensor signal, and apply the second actuation signal to the second piezoelectric actuator to produce the second counter mechanical response in response to the movement indicated by the at least one motion sensor signal.

In some implementations, a method of stabilizing a position of an image sensor includes determining, by an actuation circuit, a counter mechanical response based on a motion sensor signal corresponding to a movement sensed by a motion sensor, wherein the counter mechanical response is directionally opposed to the movement indicated by the motion sensor signal; generating, by the actuation circuit, an actuation signal based on the counter mechanical response; and providing, by the actuation circuit, the actuation signal to a piezoelectric actuator coupled to a piezoelectric-actuated MEMS platform, wherein actuation of the piezoelectric actuator causes a position shift of the piezoelectric-actuated MEMS platform to produce the counter mechanical response.

### BRIEF DESCRIPTION OF THE DRAWINGS

Implementations are described herein with reference to the appended drawings.

FIG. 1 illustrates a camera system according to one or more implementations.

FIG. 2 illustrates a cross-section of a portion of a camera module according to one or more implementations.

FIG. 3 illustrates a schematic block diagram of an actuation circuit according to one or more implementations.

FIG. 4 illustrates a platform layer of a camera module according to one or more implementations.

FIG. 5 illustrates a platform layer of a camera module according to one or more implementations.

### DETAILED DESCRIPTION

In the following, details are set forth to provide a more thorough explanation of example implementations. However, it will be apparent to those skilled in the art that these implementations may be practiced without these specific details. In other instances, well-known structures and devices are shown in block diagram form or in a schematic view, rather than in detail, in order to avoid obscuring the implementations. In addition, features of the different implementations described hereinafter may be combined with each other, unless specifically noted otherwise.

Further, equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually interchangeable.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “top,” “bottom,” “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling (e.g., any connection or coupling without additional intervening elements) may also be implemented by an indirect connection or coupling (e.g., a connection or coupling with one or more additional intervening elements, or vice versa) as long as the general purpose of the connection or coupling (e.g., to transmit a certain kind of signal or to transmit a certain kind of information) is essentially maintained. Features from different implementations may be combined to form further implementations. For example, variations or modifications described with respect to one of the implementations may also be applicable to other implementations unless noted to the contrary.

As used herein, the terms “substantially” and “approximately” mean “within reasonable tolerances of manufacturing and measurement.” For example, the terms “substantially” and “approximately” may be used herein to account for small manufacturing tolerances or other factors (e.g., within 5%) that are deemed acceptable in the industry without departing from the aspects of the implementations described herein. For example, a resistor with an approximate resistance value may practically have a resistance within 5% of the approximate resistance value. As another example, a signal with an approximate signal value may practically have a signal value within 5% of the approximate signal value.

In the present disclosure, expressions including ordinal numbers, such as “first”, “second”, and/or the like, may modify various elements. However, such elements are not limited by such expressions. For example, such expressions do not limit the sequence and/or importance of the elements. Instead, such expressions are used merely for the purpose of distinguishing an element from the other elements. For example, a first box and a second box indicate different boxes, although both are boxes. For further example, a first element could be termed a second element, and similarly, a second element could also be termed a first element without departing from the scope of the present disclosure.

Hand-held cameras may be susceptible to movement during image capture that leads to image blur. Movement may be caused by camera shake, hand jitter, and other types of camera movement. As the camera moves, so may an image sensor located within a camera module of the camera. Thus, an image may become blurred if the image sensor moves while capturing light waves for generating image data.

Some implementations disclosed herein are directed to using one or more piezoelectric actuators to stabilize an image sensor during camera movement in order to reduce or prevent image blur. For example, a motion sensor may be used to sense a movement of the camera module, and the one or more piezoelectric actuators may be used to produce a counter mechanical response (e.g., a counter movement) in order to counteract the movement sensed by the motion sensor. As a result, a position of the image sensor may be stabilized in order to reduce or prevent image blur. For example, the image sensor may be maintained in a stable or substantially stable position by the counter mechanical response provided by the one or more piezoelectric actuators in order to reduce or prevent image blur.

In some implementations, one or more piezoelectric sensors may be provided to provide localized feedback information to ensure that the counter mechanical response is counterbalanced relative to the movement sensed by the motion sensor.

In some implementations, the one or more piezoelectric actuators may be used to provide a focusing function by moving the image sensor closer to or further away from an image scene to bring one or more objects in the image scene into focus on the image sensor. The focusing function may be an autofocus function.

“Sensor” may refer to a component which converts a property to be measured to an electrical signal (e.g., a current signal or a voltage signal). The property to be measured may, for example, comprise a magnetic field, an electric field, an electromagnetic wave (e.g., a radio wave), a pressure, a force, a current, or a voltage, but is not limited thereto. For a piezoelectric sensor, the property to be measured is mechanical energy, such as a mechanical force, a mechanical movement, a mechanical displacement, and/or a mechanical deformation. The piezoelectric sensor may generate a signal, such as a voltage, when mechanical energy is applied to the piezoelectric sensor based on a piezoelectric effect. Thus, a piezoelectric sensor is a device that may use the piezoelectric effect to measure mechanical changes in pressure, acceleration, strain, or force by converting a mechanical change to electrical energy.

Conversely, a piezoelectric actuator may be a transducer that converts electrical energy into mechanical energy, such as a mechanical displacement or stress, based on a piezoelectric effect. For example, the piezoelectric actuator may convert electrical energy, such as a current or voltage, directly into linear motion. Thus, mechanical displacement or force may be proportional to the electrical energy applied to the piezoelectric actuator.

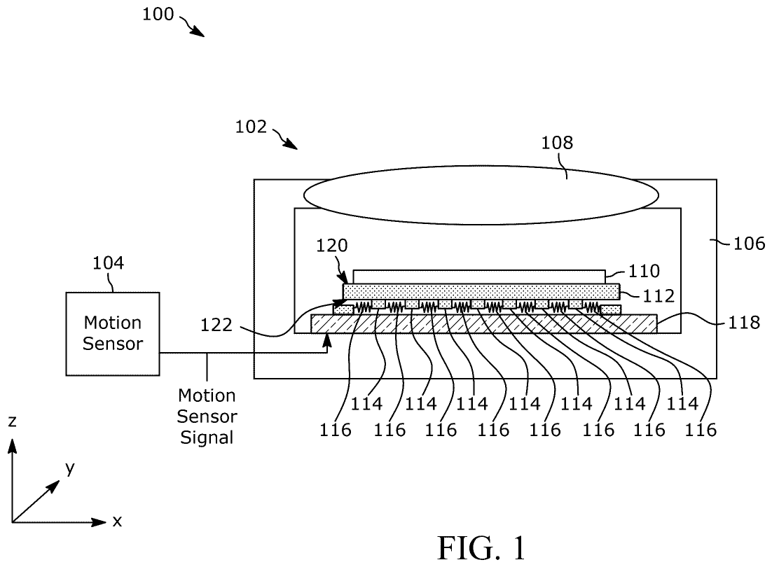

FIG. 1 illustrates a camera system 100 according to one or more implementations. The camera system 100 may include a camera module 102 and a motion sensor 104 that is external to the camera module 102 (e.g., an external motion sensor). The motion sensor 104 may be electrically coupled to the camera module 102 to provide motion sensor signals corresponding to movement to the camera module 102. The motion sensor 104 may be a gyroscope, an accelerometer, or another type of motion sensing device.

Both the camera module 102 and the motion sensor 104 may be arranged inside a housing of a device, such as a camera or a mobile phone. Thus, the device may be a portable device, such as a hand-held device.

The camera module 102 may include a housing 106, a lens 108, an image sensor 110, a movable substrate 112, one or more piezoelectric-actuated MEMS platforms 114, one or more piezoelectric actuators 116, and a circuit substrate 118. The lens 108 may be arranged over the image sensor 110 to focus light onto the image sensor 110.

The movable substrate 112 may include a first main surface 120 and a second main surface 122 that is arranged opposite to the first main surface 120. The image sensor, configured to capture image data, may be mechanically coupled to the first main surface 120.

The piezoelectric-actuated MEMS platforms 114 may be mechanically coupled to the second main surface 122 of the movable substrate 112 such that the movable substrate 112 and the piezoelectric-actuated MEMS platforms 114 are configured to move in unison. That is, a movement of the movable substrate 112 may cause the piezoelectric-actuated MEMS platforms 114 to move in a similar manner in magnitude, direction, speed, and/or acceleration to the movement of the movable substrate 112, and vice versa. In some implementations, the piezoelectric-actuated MEMS platforms 114 may be coupled together in tandem such that each piezoelectric-actuated MEMS platform 114 may act in conjunction with other piezoelectric-actuated MEMS platforms 114.

The piezoelectric actuators 116 may be mechanically coupled to the piezoelectric-actuated MEMS platforms 114. For example, one or more piezoelectric actuators 116 may be mechanically coupled to a respective piezoelectric-actuated MEMS platform 114 to provide a counter mechanical response to the respective piezoelectric-actuated MEMS platform 114. By causing the piezoelectric-actuated MEMS platforms 114 to move, the piezoelectric actuators 116 may provide a counter mechanical response to the movable substrate 112, and, ultimately, to the image sensor 110. The movement sensed by the motion sensor 104 may be caused by camera shake, hand jitter, or another type of movement that may have caused image blur if not for the counter mechanical response. Thus, the counter mechanical response applied by the piezoelectric actuators 116 to the piezoelectric-actuated MEMS platforms 114 may be used to stabilize the image sensor 110 in the event movement is sensed by the motion sensor 104.

The circuit substrate 118 may include an actuation circuit that is electrically coupled to the motion sensor 104 and to the piezoelectric actuators 116. The actuation circuit may receive the motion sensor signal corresponding to a movement from the motion sensor 104, generate at least one actuation signal based on the motion sensor signal, and provide the at least one actuation signal to at least one piezoelectric actuator 116 to produce the counter mechanical response at the movable substrate 112 in response to the movement indicated by the motion sensor signal. In other words, the piezoelectric actuators 116 may produce the counter mechanical response at the piezoelectric-actuated MEMS platforms 114, which is then transferred to the movable substrate 112 by a mechanical coupling between the piezoelectric-actuated MEMS platforms 114 and the movable substrate 112.

The counter mechanical response may be directionally opposed to the movement indicated by the motion sensor signal. For example, the counter mechanical response may be equal in magnitude to the movement indicated by the motion sensor signal in order to stabilize the camera system 100 in a stable position. The counter mechanical response may include a counter movement in a lateral plane (e.g., an x-y plane) that is parallel to the first main surface 120. Additionally, or alternatively, the counter mechanical response may include a counter movement in a vertical plane (e.g., an x-z plane or a y-z plane) that is perpendicular to the first main surface 120. The actuation circuit may determine at least one of a magnitude, a direction, a speed, or an acceleration of the movement based on the motion sensor signal. In addition, the actuation circuit may calculate the counter mechanical response based on at least one of the magnitude, the direction, the speed, or the acceleration of the movement indicated by the motion sensor signal in order to counteract the movement indicated by the motion sensor signal.

In some implementations, each piezoelectric-actuated MEMS platform 114 may be coupled to a plurality of piezoelectric actuators 116. In this case, the actuation circuit may selectively actuate one or more of the plurality of piezoelectric actuators 116 to produce the counter mechanical response at a respective piezoelectric-actuated MEMS platform 114. For example, the actuation circuit may select which piezoelectric actuators 116 to activate based on a direction of the movement indicated by the motion sensor signal. For example, some piezoelectric actuators 116 may be configured to provide counter movement along a first axis (e.g., an x-axis), some piezoelectric actuators 116 may be configured to provide counter movement along a second axis (e.g., a y-axis), and some piezoelectric actuators 116 may be configured to provide counter movement along a third axis (e.g., a z-axis). Thus, depending on the direction of the movement indicated by the motion sensor signal, the counter mechanical response may include one or more counter movements along the first axis, the second axis, and/or the third axis. Accordingly, the actuation circuit may generate at least one actuation signal to stabilize the movable substrate 112 and the image sensor 110. In some implementations, the actuation circuit may generate at least one actuation signal to maintain the movable substrate 112 at a target position.

In some implementations, one or more of the piezoelectric actuators 116 may be used to provide a focusing function, such as an autofocus function. The movable substrate 112 may be configured to move in an out-of-plane direction (e.g., a z-direction) to change a distance between the lens 108 and the image sensor 110 for focusing light from the lens 108 onto the image sensor 110. The actuator circuit may actuate one or more of the piezoelectric actuators 116 that are configured to move the movable substrate 112 in the out-of-plane direction in order to shift a position of the movable substrate 112 in the out-of-plane direction based on a focus control parameter.

In some implementations, the camera module 102 may include at least one piezoelectric sensor (not illustrated in FIG. 1) configured to sense a counter movement of one or more of the piezoelectric-actuated MEMS platforms 114 corresponding to the counter mechanical response, and generate at least one sensor feedback signal based on a piezoelectric effect corresponding to the counter movement of the one or more of the piezoelectric-actuated MEMS platforms 114. The actuator circuit may monitor the counter mechanical response based on the at least one sensor feedback signal. For example, the actuation circuit may determine a displacement corresponding to the counter movement based on the at least one sensor feedback signal, compare the displacement to a target displacement to generate a comparison result, and regulate the at least one actuation signal based on the comparison result such that the displacement is equal to a target displacement. Thus, the actuation circuit may generate the at least one actuation signal to move one or more piezoelectric-actuated MEMS platforms 114 toward a target position based on the at least one sensor feedback signal.

As indicated above, FIG. 1 is provided merely as an example. Other examples may differ from what is described with regard to FIG. 1. In some implementations, additional circuit components may be added without deviating from the disclosure provided above.

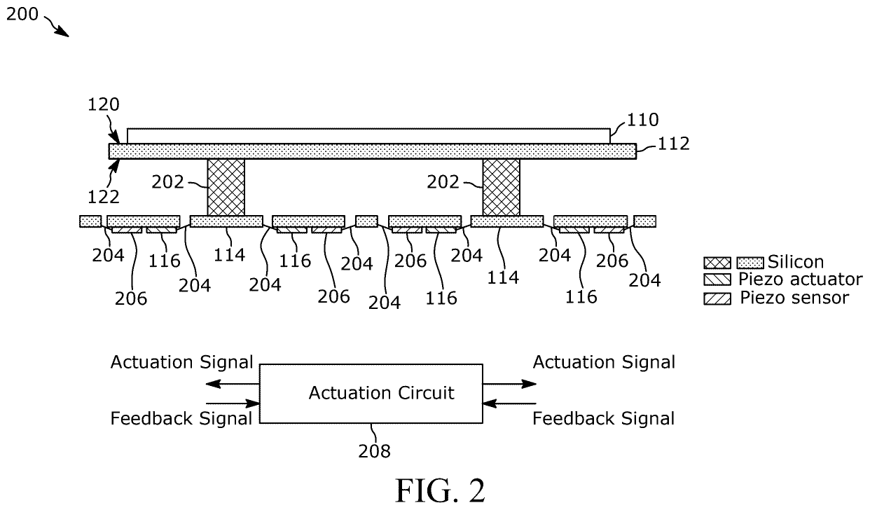

FIG. 2 illustrates a cross-section of a portion 200 of a camera module according to one or more implementations. The camera module may be similar to the camera module 102 described in connection with FIG. 1. Thus, the portion 200 of the camera module may include the image sensor 110, the movable substrate 112, the piezoelectric-actuated MEMS platforms 114, and the piezoelectric actuators 116. In addition, the portion 200 of the camera module may include columns 202 that mechanically couple a respective piezoelectric-actuated MEMS platform 114 to the second main surface 122 of the movable substrate 112. Thus, each piezoelectric-actuated MEMS platform 114 may be mechanically coupled to the second main surface 122 of the movable substrate 112 such that the movable substrate 112 and the piezoelectric-actuated MEMS platforms 114 are configured to move in unison in one or more directions. In some implementations, the movable substrate 112, the piezoelectric-actuated MEMS platforms 114, and the columns 202 may be made from silicon. In some implementations, the movable substrate 112, the piezoelectric-actuated MEMS platforms 114, and the columns 202 may form a one-piece integral construction. For example, the movable substrate 112, the piezoelectric-actuated MEMS platforms 114, and the columns 202 may be formed from a single block of silicon. In some implementations, the movable substrate 112, the piezoelectric-actuated MEMS platforms 114, and the columns 202 may be formed by etching the single block of silicon.

One or more actuator springs 204 may be used to couple each piezoelectric actuator 116 to a respective piezoelectric-actuated MEMS platform 114. Each piezoelectric actuator 116 may include a membrane that may be coupled to one or more actuator springs 204 and may be driven by an actuation signal. When an actuation signal is applied to a piezoelectric actuator 116, the actuator signal may cause a deflection of the membrane that is proportional to a magnitude of the actuator signal. For example, a thin piezoelectric film to which the actuation signal is applied may be arranged on the membrane. The deflection of the membrane may be configured to cause a position shift of a respective piezoelectric-actuated MEMS platform 114 in a corresponding actuation direction. For example, the deflection of the membrane may cause an actuator spring 204 to move, and a movement of the actuator spring 204 may cause the respective piezoelectric-actuated MEMS platform 114 to move in a corresponding actuation direction. An amount of movement may be proportional to an amount of deflection of the membrane. Thus, an actuation circuit 208 may apply the actuation signal to the membrane of a piezoelectric actuator 116 to induce the deflection of the membrane, and to cause the respective piezoelectric-actuated MEMS platform 114 to move in a corresponding actuation direction.

In some implementations, the portion 200 of the camera module may include one or more piezoelectric sensors 206 for providing localized feedback information to ensure that a counter mechanical response is counterbalanced relative to the movement sensed by the motion sensor 104. Each piezoelectric sensor 206 may be configured to monitor a position of a respective piezoelectric-actuated MEMS platform 114 and/or a deflection of a membrane of a respective piezoelectric actuator 116. For example, a piezoelectric sensor 206 may sense a counter movement of the respective piezoelectric-actuated MEMS platform 114 corresponding to the counter mechanical response, and generate at least one sensor feedback signal based on a piezoelectric effect corresponding to the counter movement of the respective piezoelectric-actuated MEMS platform 114. The actuation circuit 208 may monitor the counter mechanical response based on each sensor feedback signal. In some implementations, the actuation circuit 208 may determine a displacement corresponding to the counter movement based on each sensor feedback signal, compare the displacement to a target displacement to generate a comparison result, and regulate one or more actuation signals based on the comparison result such that the displacement is equal to a target displacement. Thus, the actuation circuit 208 may generate the actuation signals to move each piezoelectric-actuated MEMS platform 114 toward a target position based on the sensor feedback signals.

In some implementations, a piezoelectric sensor 206 may detect a mechanical deflection of a respective piezoelectric actuator 116 and generate a corresponding electrical charge. The electrical charge may be used by the actuation circuit 208 to confirm if the target displacement is reached. If the displacement is off the target displacement, the actuation circuit 208 may adjust the actuation signal to achieve the target displacement. In some implementations, a piezoelectric sensor 206 may be mechanically coupled to the respective piezoelectric-actuated MEMS platform 114 for sensing a movement of the respective piezoelectric-actuated MEMS platform 114. For example, movement of the respective piezoelectric-actuated MEMS platform 114 may cause a membrane of the piezoelectric sensor 206 to deflect, resulting in a corresponding electrical charge to be generated.

In some implementations, other types of feedback sensors may be used to provide sensor feedback signals. For example, capacitive or magnetic sensing may be used to sense a position of one or more piezoelectric-actuated MEMS platforms 114 or a position of the movable substrate 112.

As indicated above, FIG. 2 is provided as an example. Other examples may differ from what is described with regard to FIG. 2. In some implementations, additional circuit components may be added without deviating from the disclosure provided above.

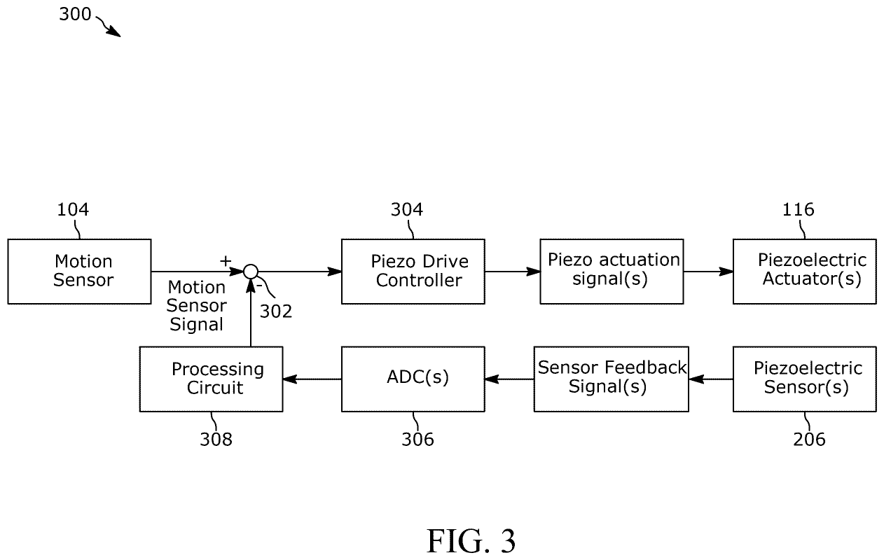

FIG. 3 illustrates a schematic block diagram of an actuation circuit 300 according to one or more implementations. The camera module may be similar to the actuation circuit (e.g., actuation circuit 208) described in connection with FIGS. 1 and 2. The actuation circuit 300 may include a compensation component 302, a piezo drive controller 304, one or more analog-to-digital converters (ADCs) 306, and a processing circuit 308 (e.g., a processor). The ADCs 306 may sample sensor feedback signals received from one or more piezoelectric sensors 206. The processing circuit 308 may process digital signals from the ADCs 306 to determine a displacement corresponding to one or more counter movements, and generate a position signal representative of the displacement. The compensation component 302 may receive the motion sensor signal and the position signal, and determine a difference value (e.g., an error value) between the motion sensor signal and the position signal. The piezo drive controller 304 may regulate one or more actuation signals based on the difference value such that the displacement is equal to a target displacement. Thus, the piezo drive controller 304 may use the difference value as a comparison result to move the movable substrate 112 toward a target position in order to counteract a movement sensed by the motion sensor 104 and to stabilize the image sensor 110.

As indicated above, FIG. 3 is provided as an example. Other examples may differ from what is described with regard to FIG. 3. In some implementations, additional circuit components may be added without deviating from the disclosure provided above.

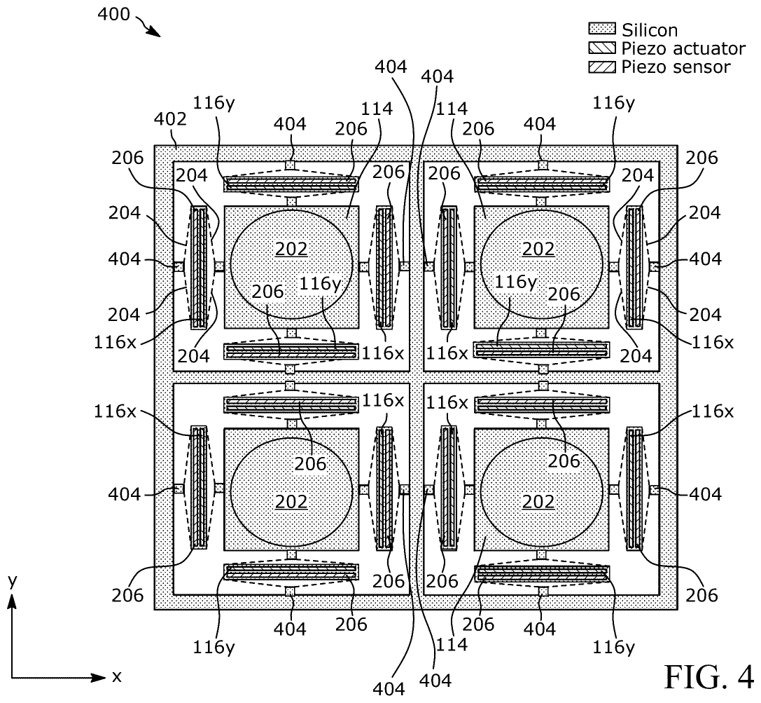

FIG. 4 illustrates a platform layer 400 of a camera module according to one or more implementations. The camera module may be similar to the camera module 102 described in connection with FIG. 1. The platform layer 400 may include a fixed frame 402 and a plurality of piezoelectric-actuated MEMS platforms 114 that are configured to move in a lateral plane (e.g., an x-y plane). Each piezoelectric-actuated MEMS platform 114 may be attached to a respective column 202. In addition, each piezoelectric-actuated MEMS platform 114 may be mechanically coupled to the fixed frame 402 by a plurality of anchors 404 or other attachment structures. Thus, each piezoelectric-actuated MEMS platform 114 may move in unison with the movable substrate 112 along the first axis (e.g., the x-axis) and the second axis (e.g., the y-axis).

Each piezoelectric-actuated MEMS platform 114 may be coupled to one or more piezoelectric actuators 116x. The piezoelectric actuators 116x may be configured to provide a first counter mechanical response to the movable substrate 112 by shifting a respective piezoelectric-actuated MEMS platform along the first axis. Thus, the piezoelectric actuators 116x may be configured to provide lateral motion along the first axis. The piezoelectric actuators 116x may be coupled to the frame 402 and to the piezoelectric-actuated MEMS platforms 114 by actuator springs 204. The piezoelectric actuators 116x may be configured to assist each other in providing the first counter mechanical response to the movable substrate 112 by shifting a respective piezoelectric-actuated MEMS platform 114 along the first axis.

In addition, each piezoelectric-actuated MEMS platform 114 may be coupled to one or more piezoelectric actuators 116y. The piezoelectric actuators 116y may be configured to provide a second counter mechanical response to the movable substrate 112 by shifting a respective piezoelectric-actuated MEMS platform along the second axis. Thus, the piezoelectric actuators 116y may be configured to provide lateral motion along the second axis. The piezoelectric actuators 116y may be coupled to the frame 402 and to the piezoelectric-actuated MEMS platforms 114 by actuator springs 204. The piezoelectric actuators 116y may be configured to assist each other in providing the second counter mechanical response to the movable substrate 112 by shifting a respective piezoelectric-actuated MEMS platform 114 along the second axis.

The actuation circuit 208 may selectively control each of the piezoelectric actuators 116x and each of the piezoelectric actuators 116y via actuation signals to produce the first counter mechanical response and the second counter mechanical response in order to counteract the movement indicated by the motion sensor signal along both the first axis and the second axis.

In addition, the platform layer 400 may include a plurality of piezoelectric sensors 206. Each piezoelectric sensor 206 may detect a mechanical deflection of a respective piezoelectric actuator 116 that is arranged adjacent to the piezoelectric sensor 206, and generate a sensor feedback signal based on the mechanical deflection. The actuation circuit 208 may receive the sensor feedback signals from the piezoelectric sensors 206, determine a displacement corresponding to a counter movement based on the sensor feedback signals, compare the displacement to a target displacement to generate a comparison result, and regulate one or more of the actuation signals based on the comparison result, such that the displacement is equal to a target displacement.

As indicated above, FIG. 4 is provided as an example. Other examples may differ from what is described with regard to FIG. 4. In some implementations, additional circuit components may be added without deviating from the disclosure provided above.

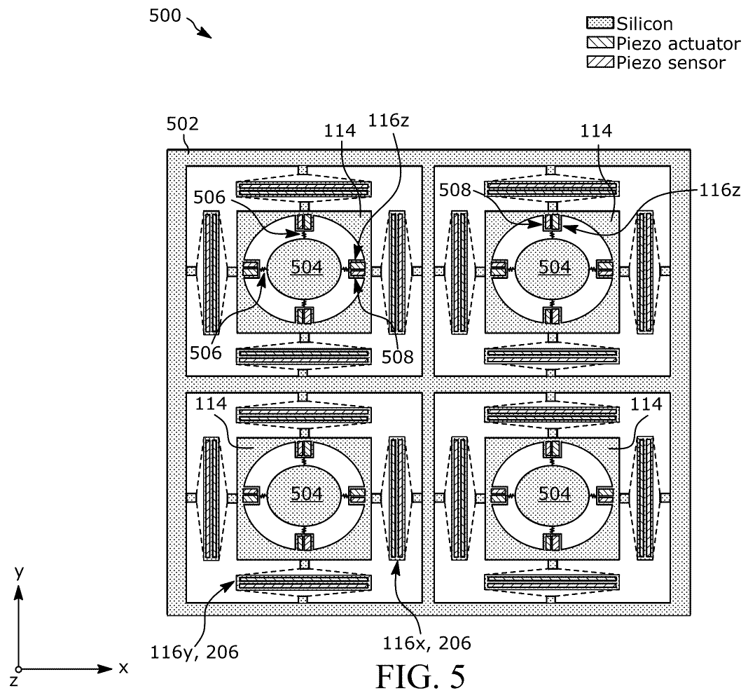

FIG. 5 illustrates a platform layer 500 of a camera module according to one or more implementations. The camera module may be similar to the camera module 102 described in connection with FIG. 1. The platform layer 500 may include a fixed frame 502, a plurality of piezoelectric-actuated MEMS platforms 114 that are configured to move in a lateral plane (e.g., an x-y plane), and a plurality of piezoelectric-actuated MEMS platforms 504 that are configured to move in a vertical plane (e.g., the x-z plane or the y-z plane). In other words, the plurality of piezoelectric-actuated MEMS platforms 504 may be configured to move in a vertical direction (e.g., a z-direction) along a third axis (e.g., the z-axis).

Each piezoelectric-actuated MEMS platform 504 may be attached to a respective column 202, and may be further attached to a respective piezoelectric-actuated MEMS platform 114. For example, a piezoelectric-actuated MEMS platform 504 may be attached to a respective piezoelectric-actuated MEMS platform 114 by one or more bending beams 506.

Thus, each piezoelectric-actuated MEMS platform 114 may move in unison with the movable substrate 112 along the first axis (e.g., the x-axis) and the second axis (e.g., the y-axis), and each piezoelectric-actuated MEMS platform 504 may move in unison with the movable substrate 112 along the third axis (e.g., the z-axis). As a result, the movable substrate 112 may move in three dimensions.

Each piezoelectric-actuated MEMS platform 114 may be coupled to one or more piezoelectric actuators 116x and to one or more piezoelectric actuators 116y, as similarly described in connection with FIG. 4.

Each piezoelectric-actuated MEMS platform 504 may be coupled to one or more piezoelectric actuators 116z. The piezoelectric actuators 116z may be configured to provide a third counter mechanical response to the movable substrate 112 by shifting a respective piezoelectric-actuated MEMS platform along the third axis. Thus, the piezoelectric actuators 116y may be configured to provide vertical motion along the third axis. A membrane of each piezoelectric actuator 116z may be coupled to a respective piezoelectric-actuated MEMS platform 114 by a bending beam 506. As a membrane of a piezoelectric actuator 116z undergoes mechanical deflection, vertical motion may be induced using the bending beam 506. The piezoelectric actuators 116z may be configured to assist each other in providing the third counter mechanical response to the movable substrate 112 by shifting a respective piezoelectric-actuated MEMS platform 504 along the third axis.

The actuation circuit 208 may generate actuation signals to be applied to the piezoelectric actuators 116z based on a motion sensor signal, and apply the actuation signals to the piezoelectric actuators 116z to produce the third counter mechanical response in response to the movement indicated by the motion sensor signal.

In addition, the platform layer 500 may include a plurality of piezoelectric sensors 508. Each piezoelectric sensor 508 may detect a mechanical deflection of a respective piezoelectric actuator 116z that is arranged adjacent to the piezoelectric sensor 508, and generate a sensor feedback signal based on the mechanical deflection. The actuation circuit 208 may receive the sensor feedback signals from the piezoelectric sensors 508, determine a displacement corresponding to a counter movement based on the sensor feedback signals, compare the displacement to a target displacement to generate a comparison result, and regulate one or more of the actuation signals based on the comparison result such that the displacement is equal to a target displacement.

In some implementations, the actuation circuit 208 may use the piezoelectric actuators 116z to perform a focusing function, such as an autofocus function. For example, the movable substrate 112 may be configured to move in an out-of-plane direction (e.g., a vertical direction or z-direction) to change a distance between the lens 108 and the image sensor 110 for focusing light from the lens 108 onto the image sensor 110. The actuator circuit 208 may actuate one or more of the piezoelectric actuators 116z to shift a position of the piezoelectric-actuated MEMS platforms 504 in the out-of-plane direction based on a focus control parameter. The focus control parameter may correspond to the autofocus function. Thus, by shifting the piezoelectric-actuated MEMS platforms 504 in the out-of-plane direction, a position of the movable substrate 112 may also be shifted in the out-of-plane direction.

As indicated above, FIG. 5 is provided as an example. Other examples may differ from what is described with regard to FIG. 5. In some implementations, additional circuit components may be added without deviating from the disclosure provided above.

The following provides an overview of some Aspects of the present disclosure:

Aspect 1: A camera module, comprising: a movable substrate comprising a first main surface and a second main surface arranged opposite to the first main surface; an image sensor configured to capture image data, wherein the image sensor is mechanically coupled to the first main surface; a piezoelectric-actuated micro-electrical-mechanical systems (MEMS) platform mechanically coupled to the second main surface of the movable substrate such that the movable substrate and the piezoelectric-actuated MEMS platform are configured to move in unison; at least one piezoelectric actuator coupled to the piezoelectric-actuated MEMS platform, wherein the at least one piezoelectric actuator is configured to provide a counter mechanical response to the piezoelectric-actuated MEMS platform; and an actuation circuit configured to receive a motion sensor signal corresponding to a movement, generate at least one actuation signal based on the motion sensor signal, and provide the at least one actuation signal to the at least one piezoelectric actuator to produce the counter mechanical response at the piezoelectric-actuated MEMS platform in response to the movement indicated by the motion sensor signal.

Aspect 2: The camera module of Aspect 1, wherein the actuation circuit is configured to receive the motion sensor signal from a motion sensor.

Aspect 3: The camera module of any of Aspects 1-2, wherein the counter mechanical response is directionally opposed to the movement indicated by the motion sensor signal.

Aspect 4: The camera module of Aspect 3, wherein the counter mechanical response is equal in magnitude to the movement indicated by the motion sensor signal.

Aspect 5: The camera module of any of Aspects 1-4, wherein the counter mechanical response includes a counter movement in a lateral plane that is parallel to the first main surface.

Aspect 6: The camera module of any of Aspects 1-5, wherein the counter mechanical response includes a counter movement in a vertical plane that is perpendicular to the first main surface.

Aspect 7: The camera module of any of Aspects 1-6, wherein the actuation circuit is configured to determine at least one of a magnitude, a direction, a speed, or an acceleration of the movement based on the motion sensor signal, and calculate the counter mechanical response based on the at least one of the magnitude, the direction, the speed, or the acceleration of the movement indicated by the motion sensor signal.

Aspect 8: The camera module of any of Aspects 1-7, wherein the piezoelectric-actuated MEMS platform is coupled to a plurality of piezoelectric actuators, and wherein the actuation circuit is configured to selectively actuate one or more of the plurality of piezoelectric actuators to produce the counter mechanical response at the piezoelectric-actuated MEMS platform.

Aspect 9: The camera module of any of Aspects 1-8, wherein the actuation circuit is configured to generate the at least one actuation signal to stabilize the movable substrate and the image sensor.

Aspect 10: The camera module of any of Aspects 1-9, wherein the actuation circuit is configured to generate at least one actuation signal to maintain the movable substrate at a target position.

Aspect 11: The camera module of any of Aspects 1-10, further comprising: one or more actuator springs, wherein each actuator spring is coupled to the piezoelectric-actuated MEMS platform and a respective piezoelectric actuator of the at least one piezoelectric actuator, wherein each piezoelectric actuator comprises a membrane coupled to a respective actuator spring, wherein a deflection of the membrane is configured to cause a position shift of the piezoelectric-actuated MEMS platform in a corresponding actuation direction, and wherein the actuator circuit is configured to apply an actuation signal to the membrane of a piezoelectric actuator to induce the deflection of the membrane.

Aspect 12: The camera module of any of Aspects 1-11, further comprising: a lens arranged over the image sensor, wherein the movable substrate is configured to move in an out-of-plane direction to change a distance between the lens and the image sensor for focusing light from the lens onto the image sensor, wherein the actuator circuit is configured to actuate one or more of the at least one piezoelectric actuator to shift a position of the piezoelectric-actuated MEMS platform in the out-of-plane direction based on a focus control parameter.

Aspect 13: The camera module of any of Aspects 1-12, further comprising: at least one piezoelectric sensor configured to sense a counter movement of the piezoelectric-actuated MEMS platform corresponding to the counter mechanical response, and generate at least one sensor feedback signal based on a piezoelectric effect corresponding to the counter movement of the piezoelectric-actuated MEMS platform, wherein the actuator circuit is configured to monitor the counter mechanical response based on the at least one sensor feedback signal.

Aspect 14: The camera module of Aspect 13, wherein the actuation circuit is configured to determine a displacement corresponding to the counter movement based on the at least one sensor feedback signal, compare the displacement to a target displacement to generate a comparison result, and regulate the at least one actuation signal based on the comparison result such that the displacement is equal to a target displacement.

Aspect 15: The camera module of Aspect 13, wherein the actuation circuit is configured to generate the at least one actuation signal to move the piezoelectric-actuated MEMS platform toward a target position based on the at least one sensor feedback signal.

Aspect 16: A camera module, comprising: a movable substrate comprising a first main surface and a second main surface arranged opposite to the first main surface; an image sensor configured to capture image data, wherein the image sensor is mechanically coupled to the first main surface; a first piezoelectric-actuated micro-electrical-mechanical systems (MEMS) platform mechanically coupled to the second main surface of the movable substrate such that the movable substrate and the first piezoelectric-actuated MEMS platform are configured to move in unison along a first axis and a second axis that is perpendicular to the first axis; a first piezoelectric actuator coupled to the first piezoelectric-actuated MEMS platform, wherein the first piezoelectric actuator is configured to provide a first counter mechanical response to the movable substrate by shifting the first piezoelectric-actuated MEMS platform along the first axis; a second piezoelectric actuator coupled to the first piezoelectric-actuated MEMS platform, wherein the second piezoelectric actuator is configured to provide a second counter mechanical response to the movable substrate by shifting the first piezoelectric-actuated MEMS platform along the second axis; and an actuation circuit configured to receive at least one motion sensor signal indicative of a movement, generate a first actuation signal based on the at least one motion sensor signal, generate a second actuation signal based on the at least one motion sensor signal, apply the first actuation signal to the first piezoelectric actuator to produce the first counter mechanical response in response to the movement indicated by the at least one motion sensor signal, and apply the second actuation signal to the second piezoelectric actuator to produce the second counter mechanical response in response to the movement indicated by the at least one motion sensor signal.

Aspect 17: The camera module of Aspect 16, further comprising: a first piezoelectric sensor configured to detect a first mechanical deflection of the first piezoelectric actuator corresponding to the first counter mechanical response, and generate a first sensor feedback signal based on the first mechanical deflection; and a second piezoelectric sensor configured to detect a second mechanical deflection of the second piezoelectric actuator corresponding to the second counter mechanical response, and generate a second sensor feedback signal based on the second mechanical deflection, wherein the actuation circuit is configured to receive the first sensor feedback signal and the second sensor feedback signal, determine a displacement corresponding to a counter movement based on the first sensor feedback signal and the second sensor feedback signal, compare the displacement to a target displacement to generate a comparison result, and regulate the at least one of the first actuation signal or the second actuation signal based on the comparison result such that the displacement is equal to a target displacement.

Aspect 18: The camera module of any of Aspects 16-17, further comprising: a second piezoelectric-actuated MEMS platform mechanically coupled to the second main surface of the movable substrate such that the movable substrate and the second piezoelectric-actuated MEMS platform are configured to move in unison along a third axis that is perpendicular to the first axis and the second axis; and a third piezoelectric actuator coupled to the second piezoelectric-actuated MEMS platform, wherein the third piezoelectric actuator is configured to provide a third counter mechanical response to the movable substrate by shifting the second piezoelectric-actuated MEMS platform along the third axis, wherein the actuation circuit is configured to generate a third actuation signal based on the at least one motion sensor signal, and apply the third actuation signal to the third piezoelectric actuator to produce the third counter mechanical response in response to the movement indicated by the at least one motion sensor signal.

Aspect 19: The camera module of Aspect 18, further comprising: a first piezoelectric sensor configured to detect a first mechanical deflection of the first piezoelectric actuator corresponding to the first counter mechanical response, and generate a first sensor feedback signal based on the first mechanical deflection; a second piezoelectric sensor configured to detect a second mechanical deflection of the second piezoelectric actuator corresponding to the second counter mechanical response, and generate a second sensor feedback signal based on the second mechanical deflection; and a third piezoelectric sensor configured to detect a third mechanical deflection of the third piezoelectric actuator corresponding to the third counter mechanical response, and generate a third sensor feedback signal based on the third mechanical deflection, wherein the actuation circuit is configured to receive the first sensor feedback signal, the second sensor feedback signal, and the third sensor feedback signal, determine a displacement corresponding to a counter movement based on the first sensor feedback signal, the second sensor feedback signal, and the third sensor feedback signal, compare the displacement to a target displacement to generate a comparison result, and regulate the at least one of the first actuation signal, the second actuation signal, or the third actuation signal based on the comparison result such that the displacement is equal to a target displacement.

Aspect 20: The camera module of Aspect 18, wherein the second piezoelectric-actuated MEMS platform is mechanically coupled to the first piezoelectric-actuated MEMS platform.

Aspect 21: The camera module of any of Aspects 16-20, further comprising: a second piezoelectric-actuated MEMS platform mechanically coupled to the second main surface of the movable substrate such that the movable substrate and the second piezoelectric-actuated MEMS platform are configured to move in unison along a third axis that is perpendicular to the first axis and the second axis; and a third piezoelectric actuator coupled to the second piezoelectric-actuated MEMS platform, wherein the third piezoelectric actuator is configured to shift the second piezoelectric-actuated MEMS platform along the third axis, wherein the actuation circuit is configured to generate a third actuation signal based on an autofocus function, and apply the third actuation signal to the third piezoelectric actuator to shift the second piezoelectric-actuated MEMS platform along the third axis.

Aspect 22: The camera module of any of Aspects 16-21, further comprising: a second piezoelectric-actuated MEMS platform mechanically coupled to the second main surface of the movable substrate such that the movable substrate and the second piezoelectric-actuated MEMS platform are configured to move in unison along the first axis and the second axis; a third piezoelectric actuator coupled to the second piezoelectric-actuated MEMS platform, wherein the third piezoelectric actuator is configured to assist in providing the first counter mechanical response to the movable substrate by shifting the second piezoelectric-actuated MEMS platform along the first axis; and a fourth piezoelectric actuator coupled to the second piezoelectric-actuated MEMS platform, wherein the second piezoelectric actuator is configured to assist in providing the second counter mechanical response to the movable substrate by shifting the second piezoelectric-actuated MEMS platform along the second axis, wherein the actuation circuit is configured to generate a third actuation signal based on the at least one motion sensor signal, generate a fourth actuation signal based on the at least one motion sensor signal, apply the third actuation signal to the third piezoelectric actuator to produce the first counter mechanical response in response to the movement indicated by the at least one motion sensor signal, and apply the fourth actuation signal to the fourth piezoelectric actuator to produce the second counter mechanical response in response to the movement indicated by the at least one motion sensor signal.

Aspect 23: The camera module of any of Aspects 16-22, further comprising: a first feedback sensor configured to sense a first counter movement of the piezoelectric-actuated MEMS platform corresponding to the first counter mechanical response, and generate a first sensor feedback signal based on the first counter movement of the piezoelectric-actuated MEMS platform; and a second feedback sensor configured to sense a second counter movement of the piezoelectric-actuated MEMS platform corresponding to the second counter mechanical response, and generate a second sensor feedback signal based on the second counter movement of the piezoelectric-actuated MEMS platform, wherein the actuation circuit is configured to determine a displacement corresponding to the first counter movement and the second counter movement based on the first sensor feedback signal and the second sensor feedback signal, compare the displacement to a target displacement to generate a comparison result, and regulate the first actuation signal and the second actuation signal based on the comparison result such that the displacement is equal to a target displacement.

Aspect 24: A method of stabilizing a position of an image sensor, comprising: determining, by an actuation circuit, a counter mechanical response based on a motion sensor signal corresponding to a movement sensed by a motion sensor, wherein the counter mechanical response is directionally opposed to the movement indicated by the motion sensor signal; generating, by the actuation circuit, an actuation signal based on the counter mechanical response; and providing, by the actuation circuit, the actuation signal to a piezoelectric actuator coupled to a piezoelectric-actuated micro-electrical-mechanical systems (MEMS) platform, wherein actuation of the piezoelectric actuator causes a position shift of the piezoelectric-actuated MEMS platform to produce the counter mechanical response.

Aspect 25: A system configured to perform one or more operations recited in one or more of Aspects 1-24.

Aspect 26: An apparatus comprising means for performing one or more operations recited in one or more of Aspects 1-24.

Aspect 27: A non-transitory computer-readable medium storing a set of instructions, the set of instructions comprising one or more instructions that, when executed by a device, cause the device to perform one or more operations recited in one or more of Aspects 1-24.

Aspect 28: A computer program product comprising instructions or code for executing one or more operations recited in one or more of Aspects 1-24.

The foregoing disclosure provides illustration and description, but is not intended to be exhaustive or to limit the implementations to the precise form disclosed. Modifications and variations are possible in light of the above disclosure or may be acquired from practice of the implementations.

Some implementations may be described herein in connection with thresholds. As used herein, “satisfying” a threshold may refer to a value being greater than the threshold, more than the threshold, higher than the threshold, greater than or equal to the threshold, less than the threshold, fewer than the threshold, lower than the threshold, less than or equal to the threshold, equal to the threshold, or the like.

As used herein, the term “component” is intended to be broadly construed as hardware, firmware, or a combination of hardware and software. It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code—it being understood that software and hardware can be designed to implement the systems and/or methods based on the description herein.

Any of the processing components may be implemented as a central processing unit (CPU) or other processor reading and executing a software program from a non-transitory computer-readable recording medium such as a hard disk or a semiconductor memory device. For example, instructions may be executed by one or more processors, such as one or more CPUs, digital signal processors (DSPs), general-purpose microprocessors, application-specific integrated circuits (ASICs), field programmable logic arrays (FPLAs), programmable logic controller (PLC), or other equivalent integrated or discrete logic circuitry. Accordingly, the term “processor,” as used herein refers to any of the foregoing structures or any other structure suitable for implementation of the techniques described herein. Software may be stored on a non-transitory computer-readable medium such that the non-transitory computer readable medium includes a program code or a program algorithm stored thereon which, when executed, causes the processor, via a computer program, to perform the steps of a method.

A controller including hardware may also perform one or more of the techniques of this disclosure. A controller, including one or more processors, may use electrical signals and digital algorithms to perform its receptive, analytic, and control functions, which may further include corrective functions. Such hardware, software, and firmware may be implemented within the same device or within separate devices to support the various techniques described in this disclosure.

A signal processing circuit and/or a signal conditioning circuit may receive one or more signals (e.g., measurement signals) from one or more components in the form of raw measurement data and may derive, from the measurement signal further information. Signal conditioning, as used herein, refers to manipulating an analog signal in such a way that the signal meets the requirements of a next stage for further processing. Signal conditioning may include converting from analog to digital (e.g., via an analog-to-digital converter), amplification, filtering, converting, biasing, range matching, isolation and any other processes required to make a signal suitable for processing after conditioning.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

Further, it is to be understood that the disclosure of multiple acts or functions disclosed in the specification or in the claims may not be construed as to be within the specific order. Therefore, the disclosure of multiple acts or functions will not limit these to a particular order unless such acts or functions are not interchangeable for technical reasons. Furthermore, in some implementations, a single act may include or may be broken into multiple sub acts. Such sub acts may be included and part of the disclosure of this single act unless explicitly excluded.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A camera module, comprising:
a movable substrate comprising a first main surface and a second main surface arranged opposite to the first main surface;
an image sensor configured to capture image data, wherein the image sensor is mechanically coupled to the first main surface;
a piezoelectric-actuated micro-electrical-mechanical systems (MEMS) platform mechanically coupled to the second main surface of the movable substrate such that the movable substrate and the piezoelectric-actuated MEMS platform are configured to move in unison;
at least one piezoelectric actuator coupled to the piezoelectric-actuated MEMS platform, wherein the at least one piezoelectric actuator is configured to provide a counter mechanical response to the piezoelectric-actuated MEMS platform; and
an actuation circuit configured to receive a motion sensor signal corresponding to a movement, generate at least one actuation signal based on the motion sensor signal, and provide the at least one actuation signal to the at least one piezoelectric actuator to produce the counter mechanical response at the piezoelectric-actuated MEMS platform in response to the movement indicated by the motion sensor signal.

2. The camera module of claim 1, wherein the actuation circuit is configured to receive the motion sensor signal from a motion sensor.

3. The camera module of claim 1, wherein the counter mechanical response is directionally opposed to the movement indicated by the motion sensor signal.

4. The camera module of claim 3, wherein the counter mechanical response is equal in magnitude to the movement indicated by the motion sensor signal.

5. The camera module of claim 1, wherein the counter mechanical response includes a counter movement in a lateral plane that is parallel to the first main surface.

6. The camera module of claim 1, wherein the counter mechanical response includes a counter movement in a vertical plane that is perpendicular to the first main surface.

7. The camera module of claim 1, wherein the actuation circuit is configured to determine at least one of a magnitude, a direction, a speed, or an acceleration of the movement based on the motion sensor signal, and calculate the counter mechanical response based on the at least one of the magnitude, the direction, the speed, or the acceleration of the movement indicated by the motion sensor signal.

8. The camera module of claim 1, wherein the piezoelectric-actuated MEMS platform is coupled to a plurality of piezoelectric actuators, and
wherein the actuation circuit is configured to selectively actuate one or more of the plurality of piezoelectric actuators to produce the counter mechanical response at the piezoelectric-actuated MEMS platform.

9. The camera module of claim 1, wherein the actuation circuit is configured to generate the at least one actuation signal to stabilize the movable substrate and the image sensor.

10. The camera module of claim 1, wherein the actuation circuit is configured to generate at least one actuation signal to maintain the movable substrate at a target position.

11. The camera module of claim 1, further comprising:
one or more actuator springs, wherein each actuator spring is coupled to the piezoelectric-actuated MEMS platform and a respective piezoelectric actuator of the at least one piezoelectric actuator,
wherein each piezoelectric actuator comprises a membrane coupled to a respective actuator spring, wherein a deflection of the membrane is configured to cause a position shift of the piezoelectric-actuated MEMS platform in a corresponding actuation direction, and
wherein the actuator circuit is configured to apply an actuation signal to the membrane of a piezoelectric actuator to induce the deflection of the membrane.

12. The camera module of claim 1, further comprising:
a lens arranged over the image sensor,
wherein the movable substrate is configured to move in an out-of-plane direction to change a distance between the lens and the image sensor for focusing light from the lens onto the image sensor,
wherein the actuator circuit is configured to actuate one or more of the at least one piezoelectric actuator to shift a position of the piezoelectric-actuated MEMS platform in the out-of-plane direction based on a focus control parameter.

13. The camera module of claim 1, further comprising:
at least one piezoelectric sensor configured to sense a counter movement of the piezoelectric-actuated MEMS platform corresponding to the counter mechanical response, and generate at least one sensor feedback signal based on a piezoelectric effect corresponding to the counter movement of the piezoelectric-actuated MEMS platform,
wherein the actuator circuit is configured to monitor the counter mechanical response based on the at least one sensor feedback signal.

14. The camera module of claim 13, wherein the actuation circuit is configured to determine a displacement corresponding to the counter movement based on the at least one sensor feedback signal, compare the displacement to a target displacement to generate a comparison result, and regulate the at least one actuation signal based on the comparison result such that the displacement is equal to a target displacement.

15. The camera module of claim 13, wherein the actuation circuit is configured to generate the at least one actuation signal to move the piezoelectric-actuated MEMS platform toward a target position based on the at least one sensor feedback signal.

16. A camera module, comprising:
a movable substrate comprising a first main surface and a second main surface arranged opposite to the first main surface;
an image sensor configured to capture image data, wherein the image sensor is mechanically coupled to the first main surface;
a first piezoelectric-actuated micro-electrical-mechanical systems (MEMS) platform mechanically coupled to the second main surface of the movable substrate such that the movable substrate and the first piezoelectric-actuated MEMS platform are configured to move in unison along a first axis and a second axis that is perpendicular to the first axis;
a first piezoelectric actuator coupled to the first piezoelectric-actuated MEMS platform, wherein the first piezoelectric actuator is configured to provide a first counter mechanical response to the movable substrate by shifting the first piezoelectric-actuated MEMS platform along the first axis;
a second piezoelectric actuator coupled to the first piezoelectric-actuated MEMS platform, wherein the second piezoelectric actuator is configured to provide a second counter mechanical response to the movable substrate by shifting the first piezoelectric-actuated MEMS platform along the second axis; and
an actuation circuit configured to receive at least one motion sensor signal indicative of a movement, generate a first actuation signal based on the at least one motion sensor signal, generate a second actuation signal based on the at least one motion sensor signal, apply the first actuation signal to the first piezoelectric actuator to produce the first counter mechanical response in response to the movement indicated by the at least one motion sensor signal, and apply the second actuation signal to the second piezoelectric actuator to produce the second counter mechanical response in response to the movement indicated by the at least one motion sensor signal.

17. The camera module of claim 16, further comprising:
a first piezoelectric sensor configured to detect a first mechanical deflection of the first piezoelectric actuator corresponding to the first counter mechanical response, and generate a first sensor feedback signal based on the first mechanical deflection; and
a second piezoelectric sensor configured to detect a second mechanical deflection of the second piezoelectric actuator corresponding to the second counter mechanical response, and generate a second sensor feedback signal based on the second mechanical deflection,
wherein the actuation circuit is configured to receive the first sensor feedback signal and the second sensor feedback signal, determine a displacement corresponding to a counter movement based on the first sensor feedback signal and the second sensor feedback signal, compare the displacement to a target displacement to generate a comparison result, and regulate the at least one of the first actuation signal or the second actuation signal based on the comparison result such that the displacement is equal to a target displacement.

18. The camera module of claim 16, further comprising:
a second piezoelectric-actuated MEMS platform mechanically coupled to the second main surface of the movable substrate such that the movable substrate and the second piezoelectric-actuated MEMS platform are configured to move in unison along a third axis that is perpendicular to the first axis and the second axis; and
a third piezoelectric actuator coupled to the second piezoelectric-actuated MEMS platform, wherein the third piezoelectric actuator is configured to provide a third counter mechanical response to the movable substrate by shifting the second piezoelectric-actuated MEMS platform along the third axis,
wherein the actuation circuit is configured to generate a third actuation signal based on the at least one motion sensor signal, and apply the third actuation signal to the third piezoelectric actuator to produce the third counter mechanical response in response to the movement indicated by the at least one motion sensor signal.

19. The camera module of claim 18, further comprising:
a first piezoelectric sensor configured to detect a first mechanical deflection of the first piezoelectric actuator corresponding to the first counter mechanical response, and generate a first sensor feedback signal based on the first mechanical deflection;
a second piezoelectric sensor configured to detect a second mechanical deflection of the second piezoelectric actuator corresponding to the second counter mechanical response, and generate a second sensor feedback signal based on the second mechanical deflection; and
a third piezoelectric sensor configured to detect a third mechanical deflection of the third piezoelectric actuator corresponding to the third counter mechanical response, and generate a third sensor feedback signal based on the third mechanical deflection,
wherein the actuation circuit is configured to receive the first sensor feedback signal, the second sensor feedback signal, and the third sensor feedback signal, determine a displacement corresponding to a counter movement based on the first sensor feedback signal, the second sensor feedback signal, and the third sensor feedback signal, compare the displacement to a target displacement to generate a comparison result, and regulate the at least one of the first actuation signal, the second actuation signal, or the third actuation signal based on the comparison result such that the displacement is equal to a target displacement.

20. The camera module of claim 18, wherein the second piezoelectric-actuated MEMS platform is mechanically coupled to the first piezoelectric-actuated MEMS platform.

21. The camera module of claim 16, further comprising:
a second piezoelectric-actuated MEMS platform mechanically coupled to the second main surface of the movable substrate such that the movable substrate and the second piezoelectric-actuated MEMS platform are configured to move in unison along a third axis that is perpendicular to the first axis and the second axis; and
a third piezoelectric actuator coupled to the second piezoelectric-actuated MEMS platform, wherein the third piezoelectric actuator is configured to shift the second piezoelectric-actuated MEMS platform along the third axis,
wherein the actuation circuit is configured to generate a third actuation signal based on an autofocus function, and apply the third actuation signal to the third piezoelectric actuator to shift the second piezoelectric-actuated MEMS platform along the third axis.

22. The camera module of claim 16, further comprising:
a second piezoelectric-actuated MEMS platform mechanically coupled to the second main surface of the movable substrate such that the movable substrate and the second piezoelectric-actuated MEMS platform are configured to move in unison along the first axis and the second axis;
a third piezoelectric actuator coupled to the second piezoelectric-actuated MEMS platform, wherein the third piezoelectric actuator is configured to assist in providing the first counter mechanical response to the movable substrate by shifting the second piezoelectric-actuated MEMS platform along the first axis; and
a fourth piezoelectric actuator coupled to the second piezoelectric-actuated MEMS platform, wherein the second piezoelectric actuator is configured to assist in providing the second counter mechanical response to the movable substrate by shifting the second piezoelectric-actuated MEMS platform along the second axis,
wherein the actuation circuit is configured to generate a third actuation signal based on the at least one motion sensor signal, generate a fourth actuation signal based on the at least one motion sensor signal, apply the third actuation signal to the third piezoelectric actuator to produce the first counter mechanical response in response to the movement indicated by the at least one motion sensor signal, and apply the fourth actuation signal to the fourth piezoelectric actuator to produce the second counter mechanical response in response to the movement indicated by the at least one motion sensor signal.

23. The camera module of claim 16, further comprising:
a first feedback sensor configured to sense a first counter movement of the piezoelectric-actuated MEMS platform corresponding to the first counter mechanical response, and generate a first sensor feedback signal based on the first counter movement of the piezoelectric-actuated MEMS platform; and
a second feedback sensor configured to sense a second counter movement of the piezoelectric-actuated MEMS platform corresponding to the second counter mechanical response, and generate a second sensor feedback signal based on the second counter movement of the piezoelectric-actuated MEMS platform,
wherein the actuation circuit is configured to determine a displacement corresponding to the first counter movement and the second counter movement based on the first sensor feedback signal and the second sensor feedback signal, compare the displacement to a target displacement to generate a comparison result, and regulate the first actuation signal and the second actuation signal based on the comparison result such that the displacement is equal to a target displacement.

24. A method of stabilizing a position of an image sensor, comprising:
determining, by an actuation circuit, a counter mechanical response based on a motion sensor signal corresponding to a movement sensed by a motion sensor, wherein the counter mechanical response is directionally opposed to the movement indicated by the motion sensor signal;
generating, by the actuation circuit, an actuation signal based on the counter mechanical response; and
providing, by the actuation circuit, the actuation signal to a piezoelectric actuator coupled to a piezoelectric-actuated micro-electrical-mechanical systems (MEMS) platform,
wherein actuation of the piezoelectric actuator causes a position shift of the piezoelectric-actuated MEMS platform to produce the counter mechanical response.
